(19) United States
(12) Patent Application Publication
(10) Pub. No.: US 2024/0260357 A1
(43) Pub. Date: Aug. 1, 2024

(54) Display Panel and Display Device

(71) Applicant: LG Display Co., Ltd., Seoul (KR)

(72) Inventors: Younghee Lee, Paju-si (KR); SunIk Park, Seoul (KR); JungBum Lim, Seoul (KR); Hyoungbin Park, Paju-si (KR)

(21) Appl. No.: 18/501,382

(22) Filed: Nov. 3, 2023

(30) Foreign Application Priority Data
Jan. 30, 2023 (KR) 10-2023-0012150

(51) Int. Cl. H10K 59/131; G09G 3/3233

(52) U.S. Cl. CPC H10K 59/131; G09G 3/3233; G09G 2300/0842; H10K 59/38

(57) ABSTRACT

A display panel and a display device are disclosed that enhance the aperture ratio of subpixels. The subpixels include first to fourth subpixels comprising first to third active patterns on the substrate. The first active pattern is electrically connected to the fourth signal line, the second active pattern is electrically connected to the second signal line or the third signal line, and the third active pattern is electrically connected to the first signal line, and at least one of the first to third active patterns includes a cutting area where the cutting areas of the first and second active patterns in the first and second subpixels overlap the emission area.

### CROSS-REFERENCE TO RELATED APPLICATION

This application claims priority from Republic of Korea Patent Application No. 10-2023-0012150, filed on Jan. 30, 2023, which is hereby incorporated by reference in its entirety.

### BACKGROUND

### Field

Embodiments of the disclosure relate to a display panel and a display device.

### Description of Related Art

A display device includes thin film transistors (TFTs), a plurality of conductive layers, and light emitting elements.

In the process of manufacturing such a display device, defects, such as bright spots or dark spots, may occur in some emission areas due to foreign matter or the like. Some display devices perform a repair process to prevent defects by disconnecting the emission area where the defect occurs from the circuit area that drives the emission area. However, this method may reduce the opening of the display device or the success rate of the repair process.

### SUMMARY

Embodiments of the disclosure relate to a display panel and a display device capable of preventing or at least reducing a reduction in opening area due to a repair pattern by using a transparent active pattern, which serves as a line, as the repair pattern.

Embodiments of the disclosure relate to a display panel and a display device capable of preventing damage to the cathode electrode and the anode electrode due to a laser radiation during a repair process by disposing at least one of a color filter, a black bank, and an overcoat layer on the active pattern.

Embodiments of the disclosure relate to a display panel and a display device capable of preventing or at least reducing defects due to an external element penetrated from the encapsulation layer disposed on the cathode electrode by preventing damage to the cathode electrode due to failure of a laser beam to reach the cathode electrode by performing a repair process using a transparent active pattern as a repair pattern.

In on embodiment, a display panel comprises: a substrate comprising plurality of subpixels, the plurality of subpixels including a first subpixel, a second subpixel, a third subpixel, and a fourth subpixel each including an emission area and a non-emission area surrounding the emission area; and a plurality of signal lines on the substrate, the plurality of signals lines including a first signal line, a second signal line, a third signal line, and a fourth signal line that are spaced apart from each other, wherein each of the first subpixel to the fourth subpixel includes a plurality of active patterns on the substrate, the plurality of active patterns including a first active pattern, a second active pattern, and a third active pattern, wherein the first active pattern of at least one of the first subpixel to the fourth subpixel is electrically connected to the fourth signal line, the second active pattern of at least one of the first subpixel to the fourth subpixel is electrically connected to one of the second signal line or the third signal line, and the third active pattern of at least one of the first subpixel to the fourth subpixel is electrically connected to the first signal line, wherein at least one of the first active pattern to the third active pattern of at least one of the first subpixel to the fourth subpixel includes a cutting area configured to disconnect the at least one of the first subpixel to the fourth subpixel from at least one of the plurality of signal lines, wherein cutting areas of the first active pattern and the second active pattern in the first subpixel and the second subpixel overlap the emission area, and wherein at least one cutting area of the first active pattern to the third active pattern in the third subpixel and the fourth subpixel is in the non-emission area.

In one embodiment, a display panel comprises: a substrate; a bank on the substrate, the bank including an opening; a subpixel on the substrate, the subpixel including a thin film transistor and a light emitting element connected to the thin film transistor, the light emitting element in the opening of the bank and including an anode electrode, a light emitting layer on the anode electrode, and a cathode electrode on the light emitting layer; a first signal line configured to supply a first signal to the subpixel; and a first active pattern comprising a first cutting area that disconnects the first signal line and the subpixel, the first cutting area overlapping the light emitting element, wherein the first active pattern comprises a material having oxide.

In one embodiment, a display panel comprises: a substrate; a bank on the substrate, the bank including an opening; a subpixel on the substrate, the subpixel including a thin film transistor and a light emitting element connected to the thin film transistor, the light emitting element in the opening of the bank and including an anode electrode, a light emitting layer on the anode electrode, and a cathode electrode on the light emitting layer; a signal line configured to supply a signal to the subpixel; and an active pattern comprising a cutting area that disconnects the signal line and the subpixel, the cutting area overlapping the bank and non-overlapping the light emitting element, wherein the active pattern comprises a material having oxide.

According to embodiments of the disclosure, there may be provided a display panel and a display device capable of preventing a reduction in opening area due to a repair pattern by using a transparent active pattern, which serves as a line, as the repair pattern.

According to embodiments of the disclosure, there may be provided a display panel and a display device capable of preventing damage to the cathode electrode and the anode electrode due to a laser radiation during a repair process by disposing at least one of a color filter, a black bank, and an overcoat layer on the active pattern.

According to embodiments of the disclosure, there may be provided a display panel and a display device capable of preventing defects due to an external element penetrated from the encapsulation layer disposed on the cathode electrode by preventing damage to the cathode electrode due to failure of a laser beam to reach the cathode electrode by performing a repair process using a transparent active pattern as a repair pattern.

### BRIEF DESCRIPTION OF DRAWINGS

The above and other objects, features, and advantages of the disclosure will be more clearly understood from the following detailed description, taken in conjunction with the accompanying drawings, in which:

FIG. 1 is a view illustrating a system configuration of a display device according to embodiments of the disclosure;

FIG. 2 is an equivalent circuit diagram illustrating a subpixel of a display device according to embodiments of the disclosure;

FIG. 3 is a plan view illustrating a portion of a display area of a display device according to embodiments of the disclosure.

FIG. 4 is a cross-sectional view taken along line A-B of FIG. 3 according to embodiments of the disclosure;

FIG. 5 is a view schematically illustrating a laser radiation to an active pattern in a process of repairing a first subpixel or a second subpixel according to embodiments of the disclosure;

FIG. 6 is a graph illustrating transmittance for each wavelength of a red color filter, a green color filter, and a blue color filter;

FIG. 7 is a view schematically illustrating a laser radiation to a fifth cutting area of a first active pattern in a process of repairing the first subpixel of FIG. 3 according to embodiments of the disclosure;

FIG. 8 is a graph illustrating transmittance for each wavelength of each of a transparent bank and a black bank;

FIG. 9 is a view schematically illustrating a laser radiation to a third cutting area of a seventh active pattern in a process of repairing the third subpixel of FIG. 3 according to embodiments of the disclosure;

FIG. 10 is a view illustrating a structure of first to fourth subpixels included in a display panel according to embodiments of the disclosure;

FIG. 11 is a view schematically illustrating a laser radiation to a first cutting area of a third active pattern in a process of repairing a first subpixel according to embodiments of the disclosure;

FIG. 12 is a view schematically illustrating a laser radiation to a third cutting area of a seventh active pattern in a process of repairing the third subpixel of FIG. 10 according to embodiments of the disclosure; and

FIG. 13 is a table comparing an aperture ratio of a display panel according to a comparative example and an aperture ratio of a display panel according to an embodiment.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

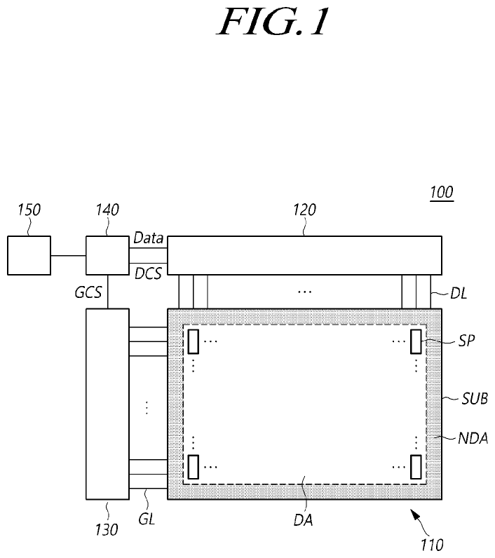

FIG. 1 is a view illustrating a system configuration of a display device according to embodiments of the disclosure. Referring to FIG. 1, a display driving system of a display device 100 according to embodiments of the disclosure may include a display panel 110 and display driving circuits for driving the display panel 110.

The display panel 110 may include a display area DA in which images are displayed and a non-display area NDA in which no image is displayed. The display panel 110 may include a plurality of subpixels SP disposed on a substrate SUB for image display. For example, the plurality of subpixels SP may be disposed in the display area DA. In some cases, at least one subpixel SP may be disposed in the non-display area NDA. At least one subpixel SP disposed in the non-display area NDA is also referred to as a dummy subpixel.

The display panel 110 may include a plurality of signal lines disposed on the substrate SUB to drive the plurality of subpixels SP. For example, the plurality of signal lines may include data lines DL, gate lines GL, driving voltage lines, and the like that are connected to the plurality of subpixels SP. The signal lines are configured to supply signals to the plurality of subpixels SP such as gate signals, data signals, and power signals, for example.

The plurality of data lines DL and the plurality of gate lines GL may cross each other. Each of the plurality of data lines DL may be disposed while extending in a first direction. Each of the plurality of gate lines GL may be disposed while extending in a direction crossing the first direction. Here, the first direction may be a column direction and the direction crossing the first direction may be a row direction.

The display driving circuits may include a data driving circuit 120, a gate driving circuit 130, and a controller 140 controlling the data driving circuit 120 and the gate driving circuit 130. The data driving circuit 120 may output data signals (also referred to as data voltages) corresponding to an image signal to the plurality of data lines DL. The gate driving circuit 130 may generate gate signals and output the gate signals to the plurality of gate lines GL. The controller 140 may convert the input image data input from an external host 150 to meet the data signal format used in the data driving circuit 120 and supply the converted image data to the data driving circuit 120.

The data driving circuit 120 may include one or more source driver integrated circuits. For example, each source driver integrated circuit may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 130 may be connected to the display panel 110 by a tape automatic bonding (TAB) method, connected to a bonding pad of the display panel 110 by a COG or COP method, connected to the display panel 110 by a COF method, or may be formed in the non-display area NDA of the display panel 110 by a gate in panel (GIP) method.

The display device 100 according to embodiments of the disclosure may be a self-emission display device in which the display panel 110 emits light by itself. For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

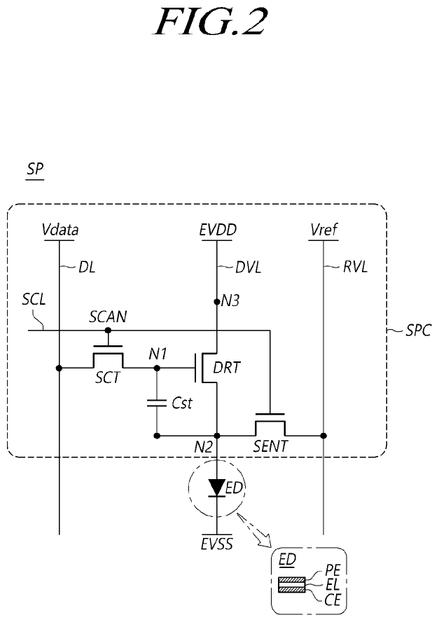

FIG. 2 is an equivalent circuit diagram illustrating a subpixel SP of a display device 100 according to embodiments of the disclosure.

Referring to FIG. 2, in the display device 100 according to embodiments of the disclosure, each subpixel SP may include a light emitting element ED and a pixel driving circuit SPC for driving the light emitting element ED. The pixel driving circuit SPC may include a driving transistor DRT, a scan transistor SCT, and a storage capacitor Cst.

The driving transistor DRT may control a current flowing to the light emitting element ED to drive the light emitting element ED. The scan transistor SCT may transfer the data voltage Vdata to the first node N1 which is the gate node of the driving transistor DRT. The storage capacitor Cst may be configured to maintain a voltage for a predetermined period of time.

The light emitting element ED may include an anode electrode AE and a cathode electrode CE, and a light emitting layer EL positioned between the anode electrode AE and the cathode electrode CE. The anode electrode AE may be electrically connected to the second node N2 of the driving transistor DRT.

A base voltage EVSS may be applied to the cathode electrode CE. The light emitting element ED may be an organic light emitting diode OLED, an inorganic material-based light emitting diode LED, or a quantum dot light emitting element, for example.

The driving transistor DRT is a transistor for driving the light emitting element ED, and may include a first node N1, a second node N2, and a third node N3. The first node N1 is a gate node and may be electrically connected to the source node or drain node of the scan transistor SCT. The second node N2 may be a source node or a drain node, and may be electrically connected to the anode electrode AE of the light emitting element ED. The third node N3 may be a drain node or a source node, and may be electrically connected to a driving voltage line DVL that supplies the driving voltage EVDD. For convenience of description, in the example described below, the second node N2 may be a source node and the third node N3 may be a drain node.

The scan transistor SCT may switch the connection between the data line DL and the first node N1 of the driving transistor DRT. In response to the scan signal SCAN supplied from the scan line SCL which is a kind of the gate line GL, the scan transistor SCT may control connection between the first node N1 of the driving transistor DRT and a corresponding data line DL among the plurality of data lines DL.

The drain node or source node of the scan transistor SCT may be electrically connected to a corresponding data line DL. The source node or drain node of the scan transistor SCT may be electrically connected to the first node N1 of the driving transistor DRT. The gate node of the scan transistor SCT may be electrically connected to the scan line SCL to receive the scan signal SCAN. The scan transistor SCT may be turned on by the scan signal SCAN of a turn-on level voltage and transfer the data voltage Vdata supplied from the data line DL to the first node N1 of the driving transistor DRT.

Referring to FIG. 2, the storage capacitor Cst may be configured between the first node N1 and second node N2 of the driving transistor DRT.

Referring to FIG. 2, in the display device 100 according to embodiments of the disclosure, the pixel driving circuit SPC of each subpixel SP may further include a sensing transistor SENT. The sensing transistor SENT may switch the connection between the second node N2 of the driving transistor DRT and the reference voltage line RVL to which the reference voltage Vref is applied.

In response to the scan signal SCAN supplied from the scan line SCL, the sensing transistor SENT may control connection between the second node N2 of the driving transistor DRT electrically connected to the anode electrode AE of the light emitting element ED and a corresponding reference voltage line RVL among the plurality of reference voltage lines RVL. In FIG. 2, the gate node of the sensing transistor SENT and the gate node of the scan transistor SCT are connected to the same scan line SCL, but this is merely an example for convenience of description, and they may be connected to different scan lines SCL.

The drain node or source node of the sensing transistor SENT may be electrically connected to the reference voltage line RVL. The source node or drain node of the sensing transistor SENT may be electrically connected to the second node N2 of the driving transistor DRT and may be electrically connected to the anode electrode AE of the light emitting element ED. The gate node of the sensing transistor SENT may be electrically connected to the scan line SCL to receive the scan signal SCAN.

Each of the driving transistor DRT, the scan transistor SCT, and the sensing transistor SENT may be an n-type transistor or a p-type transistor.

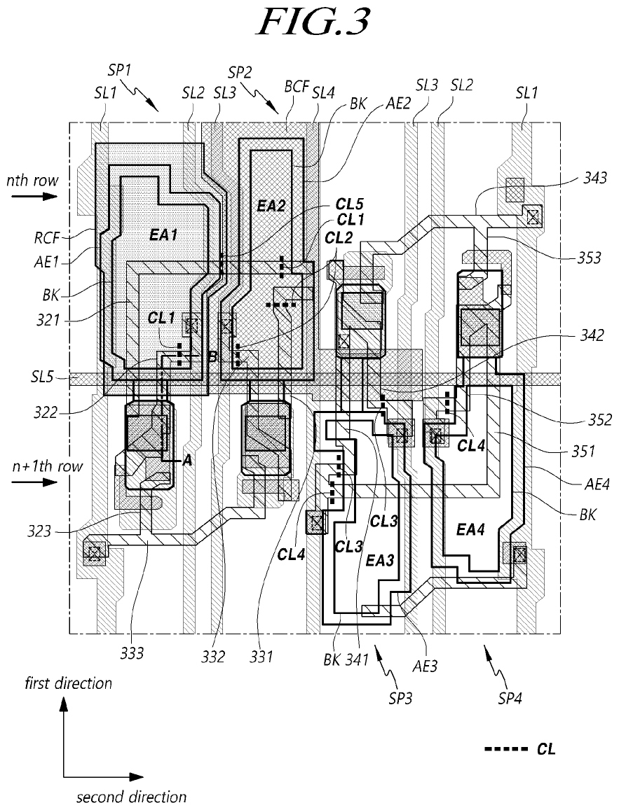

FIG. 3 is a plan view illustrating a portion of a display area of a display device according to embodiments of the disclosure.

Referring to FIG. 3, the display panel 110 according to embodiments of the disclosure may include a plurality of subpixels SP1, SP2, SP3, and SP4 disposed in the display area DA.

The subpixels SP1, SP2, SP3, and SP4 may include emission areas EA1, EA2, EA3, and EA4, respectively. For example, as illustrated in FIG. 3, a first subpixel SP1 may include a first emission area EA1, a second subpixel SP2 may include a second emission area EA2, a third subpixel SP3 may include a third emission area EA3, and a fourth subpixel SP4 may include a fourth emission area EA4.

The first emission area EA1 may be a red emission area, the second emission area EA2 may be a blue emission area, the third emission area EA3 may be a white emission area, and the fourth emission area EA4 may be a green emission area, but embodiments of the disclosure are not limited thereto.

The display panel 110 may include a non-emission area surrounding a plurality of emission areas EA1, EA2, EA3, and EA4.

The plurality of emission areas EA1, EA2, EA3, and EA4 may correspond to the opening of the bank BK, and the non-emission area may be an area in which the bank BK is disposed.

A plurality of signal lines for driving the light emitting elements disposed in the plurality of emission areas EA1, EA2, EA3, and EA4 may be disposed in the non-emission area, and a circuit unit including a plurality of transistors and a plurality of storage capacitors may also be disposed in the non-emission area.

For example, referring to FIG. 3, first to fifth signal lines SL1, SL2, SL3, SL4, and SL5 may be disposed in the non-emission area of the display panel 110.

Referring to FIG. 3, the first to fourth signal lines SL1, SL2, SL3, and SL4 may be disposed to be spaced apart from each other and extend in a first direction (e.g., column or vertical direction).

The first signal line SL1 may be a driving voltage line, the second and third signal lines SL2 and SL3 may be data lines, and the fourth signal line SL4 may be a reference voltage line, but embodiments of the disclosure are not limited thereto.

The fifth signal line SL5 may be disposed to extend in a second direction (e.g., row direction or horizontal direction) that is a direction crossing the first direction. The fifth signal line SL5 may overlap the first to fourth signal lines SL1, SL2, SL3, and SL4.

The fifth signal line SL5 may be a scan line, but embodiments of the disclosure are not limited thereto.

Referring to FIG. 3, the display panel 110 may include a plurality of anode electrodes AE1, AE2, AE3, and AE4 respectively overlapping the first to fourth emission areas EA1, EA2, EA3, and EA4.

Specifically, the first emission area EA1 of the first subpixel SP1 may overlap a portion of the first anode electrode AE1, and the second emission area EA2 of the second subpixel SP2 may overlap a portion of the second anode electrode AE2. Further, the third emission area EA3 of the third subpixel SP3 may overlap a portion of the third anode electrode AE3, and the fourth emission area EA4 of the fourth subpixel SP4 may overlap a portion of the fourth anode electrode AE4.

Referring to FIG. 3, the first emission area EA1 may overlap the first color filter RCF, and the second emission area EA2 may overlap the second color filter BCF. Further, a color filter may not be disposed in the third emission area EA3, but embodiments of the disclosure are not limited thereto.

Further, in the first and second subpixels SP1 and SP2, the first color filter RCF and the second color filter BCF may be disposed not only in the emission areas EA1 and EA2 but also in a portion of the non-emission area. A color filter (e.g., a green color filter) may also be disposed in the fourth subpixel SP4 so as to correspond to (e.g., overlap) the fourth emission area EA4 of the fourth subpixel SP4, and be not disposed in the non-emission area of the fourth subpixel SP4.

Referring to FIG. 3, the display panel 110 according to embodiments of the disclosure may include active patterns overlapping at least one anode electrode among a plurality of anode electrodes.

For example, each of the first and second anode electrodes AE1 and AE2 may overlap at least one active pattern that is electrically connected to the signal line.

A portion of at least one active pattern among the active patterns overlapping the first and second anode electrodes AE1 and AE2 may also overlap the emission area EA of the display panel 110. In other words, at least one active pattern disposed in the display area DA of the display panel 110 may overlap the anode electrode and the emission area.

Specifically, the first subpixel SP1 including the first emission area EA1 may include a first active pattern 321, a second active pattern 322, and a third active pattern 323.

A circuit unit of the first subpixel SP1 may include a scan transistor SCT, a sense transistor SENT, and a driving transistor DRT (see FIG. 2).

The first active pattern 321 disposed in the first subpixel SP1 may be electrically connected to the fourth signal line SL4. The second active pattern 322 may be electrically connected to the second signal line SL2. The third active pattern 323 may be electrically connected to the first signal line SL1.

The first active pattern 321 may be electrically connected to the sense transistor SENT of the first subpixel SP1, the second active pattern 322 may be electrically connected to the scan transistor SCAN of the first subpixel SP1, and the third active pattern 323 may be electrically connected to the driving transistor DRT of the first subpixel SP1.

Each of the first to third active patterns 321, 322, and 323 disposed in the first subpixel SP1 may be connected to signal lines disposed on the substrate to function as lines.

As illustrated in FIG. 3, the first emission area EA1 included in the first subpixel SP1 may overlap a portion of the first active pattern 321 and a portion of the second active pattern 322. Here, a portion of the first active pattern 321 may also overlap a portion of the second emission area EA2.

At least one of the first active pattern 321 and the second active pattern 322 may have a cutting area CL, which is a portion that is irradiated with a laser beam during a repair process.

The cutting area CL of an active pattern may be a portion to which a laser beam is radiated to repair a defective subpixel SP. The defective subpixel SP is repaired by generating the cutting area CL thereby disconnecting the defective subpixel SP from the signal line that is connected to the active pattern that includes the cutting area CL.

When the laser beam is radiated to the cutting area CL of the active pattern, the active pattern may be cut in the cutting area CL. When the laser beam is not radiated, the active pattern is not cut and the signal may be transferred to the thin film transistor. In other words, the cutting area CL may be identified through whether the active pattern is cut after the repair process. Further, in the active pattern where the repair process is not performed, the cutting area CL is not recognized.

In a process of manufacturing a display panel included in a display device, defects may occur in each subpixel due to a foreign substance or the like. As described above, when a subpixel is defective, the defective subpixel may be stopped from operating for repair purposes.

The repair process may mean a process of electrically opening at least one line disposed in the subpixel SP. For example, the repair process may be done by breaking the electrical connection between the corresponding line and another signal line by radiating a laser beam to the line electrically connected to at least one of the first to fourth signal lines SL1, SL2, SL3, and SL4.

In the display panel 110 according to embodiments of the disclosure, the plurality of active patterns 321, 322, 331, 332, 341, 342, 351, and 352 may serve not only as a repair pattern which is irradiated with a laser beam during a repair process, but also as lines.

For example, referring to FIG. 3, the second active pattern 322 may include at least one first cutting area CL1 in an area overlapping the first anode electrode AE1 and the first emission area EA1.

Further, referring to FIG. 3, the first active pattern 321 may include at least one first cutting area CL1 in an area overlapping the second anode electrode AE2 and the second emission area EA2 of the second subpixel SP2. In other words, the first active pattern 321 functions as a line for supplying a reference voltage signal to the first subpixel SP1, but may have the first cutting area CL1 in the area where the second subpixel SP2 is disposed.

However, embodiments of the disclosure are not limited thereto, and the first active pattern 321 may include the first cutting area CL1 in an area overlapping the first anode electrode AE1 or in an area overlapping the first anode electrode AE1 and the first emission area EA1.

Referring to FIG. 3, the second subpixel SP2 including the second emission area EA2 may include a fourth active pattern 331, a fifth active pattern 332, and a sixth active pattern 333.

The circuit unit of the second subpixel SP2 may also include a scan transistor SCT, a sense transistor SENT, and a driving transistor DRT (see FIG. 2).

The fourth active pattern 331 of the second subpixel SP2 may be electrically connected to the fourth signal line SL4, and the fifth active pattern 332 may be electrically connected to the third signal line SL3. The sixth active pattern 333 may be electrically connected to the first signal line SL1.

Referring to FIG. 3, the third active pattern 323 disposed in the first subpixel SP1 may have a structure branched from the sixth active pattern 333, but the structure of the active patterns according to the embodiments of the disclosure is not limited thereto.

The fourth active pattern 331 may be electrically connected to the sense transistor SENT of the second subpixel SP2, the fifth active pattern 332 may be electrically connected to the scan transistor SCAN of the second subpixel SP2, and the sixth active pattern 333 may be electrically connected to the driving transistor DRT of the second subpixel SP2.

Each of the fourth to sixth active patterns 331, 332, and 333 disposed in the second subpixel SP2 may be connected to signal lines disposed on the substrate to serve as a line.

As illustrated in FIG. 3, the second anode electrode AE2 and the second emission area EA2 included in the second subpixel SP2 may overlap a portion of the fourth active pattern 331 and a portion of the fifth active pattern 332.

At least one of the fourth active pattern 331 and the fifth active pattern 332 may have a cutting area CL that is a portion irradiated with a laser beam during a repair process.

For example, referring to FIG. 3, at least one of the fourth active pattern 331 and the fifth active pattern 332 may include at least one second cutting area CL2 in an area overlapping the second anode electrode AE2 and the second emission area EA2.

Referring to FIG. 3, the third subpixel SP3 including the third emission area EA3 may include a seventh active pattern 341, an eighth active pattern 342, and a ninth active pattern 343.

The circuit unit of the third subpixel SP3 may include a scan transistor SCT, a sense transistor SENT, and a driving transistor DRT (see FIG. 2).

The seventh active pattern 341 of the third subpixel SP3 may be electrically connected to the fourth signal line SL4, and the eighth active pattern 342 may be electrically connected to the third signal line SL3. The ninth active pattern 343 may be electrically connected to the first signal line SL1.

The seventh active pattern 341 may be electrically connected to the sense transistor SENT of the third subpixel SP3, the eighth active pattern 342 may be electrically connected to the scan transistor SCAN of the third subpixel SP3, and the ninth active pattern 343 may be electrically connected to the driving transistor DRT of the third subpixel SP3.

Each of the seventh to ninth active patterns 341, 342, and 343 disposed in the third subpixel SP3 may be connected to signal lines disposed on the substrate to serve as a line.

Referring to FIG. 3, at least a portion of each of the seventh to ninth active patterns 341, 342, and 343 may not overlap the third anode electrode AE3 and the third emission area EA3.

Here, the third anode electrode AE3 may be disposed in a row different from the row in which the first and second anode electrodes AE1 and AE2 are disposed. For example, when the first and second anode electrodes AE1 and AE2 are disposed in an nth row, the third anode electrode AE3 may be disposed in an n+1th row (where n is a positive number of 1 or more). Rows in which the anode electrodes are disposed may be divided with respect to the fifth signal line SL5.

Referring to FIG. 3, at least one of the seventh and eighth active patterns 341 and 342 of the seventh to ninth active patterns 341, 342, and 343 may include at least one third cutting area CL3 in an area overlapping the bank BK. In other words, the third cutting area CL3 may be disposed in a non-emission area.

The third cutting area CL3 provided in the seventh and eighth active patterns 341 and 342 may be disposed in a non-emission area of the third subpixel SP3.

The circuit unit of the fourth subpixel SP4 may include a scan transistor SCT, a sense transistor SENT, and a driving transistor DRT (see FIG. 2).

The tenth active pattern 351 of the fourth subpixel SP4 may be electrically connected to the fourth signal line SL4, and the eleventh active pattern 352 may be electrically connected to the second signal line SL2. The twelfth active pattern 353 may be electrically connected to the first signal line SL1.

The tenth active pattern 351 may be electrically connected to the sense transistor SENT of the fourth subpixel SP4, the eleventh active pattern 352 may be electrically connected to the scan transistor SCAN of the fourth subpixel SP4, and the twelfth active pattern 353 may be electrically connected to the driving transistor DRT of the fourth subpixel SP4.

Each of the tenth to twelfth active patterns 351, 352, and 353 disposed in the fourth subpixel SP4 may be connected to signal lines disposed on a substrate to serve as a line.

Referring to FIG. 3, a portion of each of the tenth to twelfth active patterns 351, 352, and 353 may not overlap the fourth anode electrode AE4 and the fourth emission area EA4.

Here, the fourth anode electrode AE4 may be disposed in a row different from the row in which the first and second anode electrodes AE1 and AE2 are disposed. For example, when the first and second anode electrodes AE1 and AE2 are disposed in an nth row, the fourth anode electrode AE4 may be disposed in an n+1th row.

Referring to FIG. 3, at least one of the tenth and eleventh active patterns 351 and 352 among the tenth to twelfth active patterns 351, 352, and 353 may include at least one fourth cutting area CL4 in an area overlapping the bank BK. In other words, the fourth cutting area CL4 may be disposed in a non-emission area.

For example, the tenth active pattern 351 may include at least one fourth cutting area CL4 in the non-emission area of the third subpixel SP3, and the eleventh active pattern 352 may include at least one fourth cutting area CL4 in the non-emission area of the fourth subpixel SP4, but embodiments of the disclosure are not limited thereto. The fourth cutting area CL4 of the tenth active pattern 351 may be provided in a non-emission area of the fourth subpixel SP4.

Referring to FIG. 3, the first to third signal lines SL1, SL2, and SL3 electrically connected to the active patterns 322, 323, 332, and 333 disposed in the first and second subpixels SP1 and SP2 may be signal lines different from the first to third signal lines SL1, SL3, and SL3 electrically connected to the active patterns 342, 343, 352, and 353 disposed in the third and fourth subpixels SP3 and SP4.

Further, referring to FIG. 3, the fourth signal line SL4 electrically connected to the active patterns 321 and 331 disposed in the first and second subpixels SP1 and SP2 may be the same signal line as the fourth signal line SL4 electrically connected to the active patterns 341 and 351 disposed in the third and fourth subpixels SP3 and SP4.

Referring to FIG. 3, at least one of the active patterns 321, 322, 331, 332, 341, and 351 overlapping the first to fourth emission areas EA1, EA2, EA3, and EA4 may include a cutting area CL. The active pattern including the cutting area CL may be connected to a data line or may be connected to a reference voltage line.

As described above, at least one of the first active pattern 321, the second active pattern 322, the fourth active pattern 331, and the fifth active pattern 532 disposed in the first and second subpixels SP1 and SP2 may include at least one cutting area CL in an area overlapping one anode electrode AE and one emission area EA.

Further, at least one of the seventh active pattern 341, the eighth active pattern 342, the tenth active pattern 351, and the eleventh active pattern 352 disposed in the third and fourth subpixels SP3 and SP4 may include at least one cutting area CL in an area overlapping the bank BK.

As described above, a laser beam may be radiated to the cutting area CL provided in the active patterns 321, 322, 331, 332, 341, 342, 351, and 352, and the area irradiated with the laser beam may be electrically disconnected from other components, and thus a signal may not be applied to the corresponding subpixel.

Since the first and second cutting areas CL1 and CL2 of the active patterns 321, 322, 331, and 332 capable of repairing the first and second subpixels SP1 and SP2 are disposed to overlap the emission areas EA1 and EA2, a repair area may be provided without decreasing the aperture ratio of the display panel 110.

Further, as the third and fourth cutting areas CL3 and CL4 of the active patterns 341, 342, 351, and 352 capable of repairing the third and fourth subpixels SP3 and SP4 are disposed to overlap the bank BK, it is possible to prevent color mixing in the area in which the color filter is not disposed and to prevent damage to the cathode electrode as the remaining laser beam radiated in the repair process is absorbed by the bank BK.

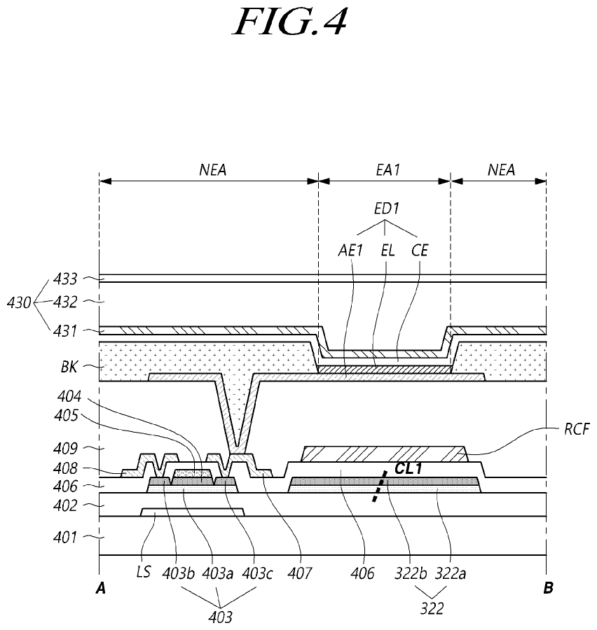

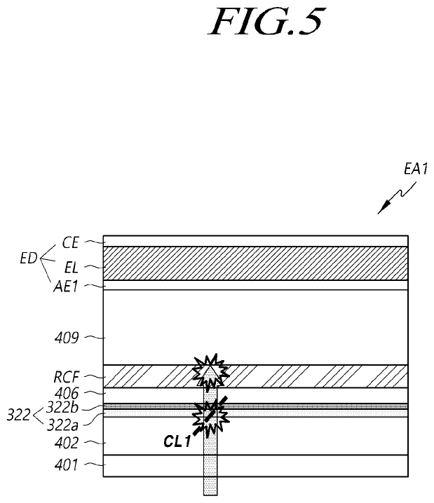

The structure of the active pattern including the cutting area CL is described below in detail with reference to FIGS. 4 and 5.

FIG. 4 is a cross-sectional view taken along line A-B of FIG. 3 according to one embodiment. FIG. 5 is a view schematically illustrating a laser radiation to an active pattern in a process of repairing a first subpixel or a second subpixel.

Referring to FIG. 4, the display panel 110 according to embodiments of the disclosure may include at least one thin film transistor disposed on the substrate 401 and a light emitting element ED1 disposed on the thin film transistor.

The thin film transistor may include an active layer 403, a gate electrode 405, a source electrode 407, and a drain electrode 408.

The light emitting element ED1 may include a first anode electrode AE1, a light emitting layer EL, and a cathode electrode CE.

In FIG. 4, the thin film transistor that is electrically connected to the light emitting element ED1 may be the driving transistor DRT.

The structure of the transistor illustrated in FIG. 4 may be the same as the structure of the scan transistor SCAN or sense transistor SENT disposed in the display area DA, and may be the same as the structure of the transistor disposed in the non-display area NDA.

Referring to FIG. 4, a light shield layer LS may be disposed on the substrate 401.

The light shield layer LS may serve to prevent or at least reduce light from being incident on the channel areas of the active layer 403 disposed in the subpixels SP.

A buffer layer 402 may be disposed on the light shield layer LS.

The buffer layer 402 may include an inorganic insulating material, such as silicon oxide (SiOx), silicon nitride (SiNx), or silicon oxynitride (SiON), but the disclosure is not limited thereto.

In FIG. 4, the buffer layer 402 has a single-layer structure, but the buffer layer 402 of the disclosure may have a multi-layer structure.

If the buffer layer 402 has a multi-layer structure, layers including at least two inorganic insulating materials among inorganic materials, such as silicon oxide (SiOx), silicon nitride (SiNx), or silicon oxynitride (SiON), may be alternately disposed, but the disclosure is not limited thereto.

The active layer 403 of the thin film transistor and the second active pattern 322 may be disposed on the buffer layer 402.

Referring to FIG. 4, the active layer 403 may include a first active layer 403a and a first auxiliary electrode 403b and a second auxiliary electrode 403c disposed on the first active layer 403a,

The first auxiliary electrode 403b and the second auxiliary electrode 403c may be disposed to be spaced apart from each other on the first active layer 403a and not overlap the channel area of the first active layer 403a. The channel area of the first active layer 403a may overlap the gate electrode 405.

The second active pattern 322 may include a second pattern 322b disposed on a first pattern 322a.

The first active layer 403a and the first pattern 322a may include an oxide semiconductor material. The oxide semiconductor material is a semiconductor material produced by controlling conductivity and adjusting the band gap through doping an oxide material, and may generally be a transparent semiconductor material having a wide band gap. For example, the oxide semiconductor material may include indium gallium zinc oxide (IGZO), zinc oxide (ZnO), cadmium oxide (CdO), indium oxide (InO), zinc tin oxide (ZTO), zinc indium tin oxide (ZITO), indium gallium zinc tin oxide (IGZTO), and the like. When the first active layer 403a is an oxide semiconductor material, the thin film transistor including the first active layer 403a is referred to as an oxide thin film transistor.

The first auxiliary electrode 403b, the second auxiliary electrode 403c, and the second pattern 322b may include conductive oxide. For example, the conductive oxide may include at least one of a transparent conductive oxide (TCO), a nitric oxide, an organic material, or the like. For example, the transparent conductive oxide TCO may include one or more of indium zinc oxide (IZO), indium tin oxide (ITO), zinc oxide (ZnO), aluminum-doped zinc oxide (AZO), gallium-doped zinc oxide (GZO), antimony tin oxide (ATO), and fluorine-doped transparent oxides (FTO). The nitric oxide may include zinc oxynitride (ZnON) or the like.

The first auxiliary electrode 403b may be disposed between the first active layer 403a and the drain electrode 408 to electrically connect the first active layer 403a and the drain electrode 408. The second auxiliary electrode 403c may be disposed between the first active layer 403a and the source electrode 407 to electrically connect the first active layer 403a and the source electrode 407.

A gate insulation film 404 may be disposed on the first active layer 403a.

The gate insulation film 404 may be disposed on the channel area of the first active layer 403a.

A gate electrode 405 may be disposed on the gate insulation film 404.

Referring to FIG. 4, an inter-layer insulation film 406 may be disposed on the substrate on which the gate electrode 405 is disposed.

Referring to FIG. 4, the inter-layer insulation film 406 may include contact holes exposing portions of the respective upper surfaces of the first auxiliary electrode 403b and the second auxiliary electrode 403c.

The drain electrode 408 may be disposed on the inter-layer insulation film 406 and contact a portion of the upper surface of the first auxiliary electrode 403b through the contact hole. The source electrode 407 may be disposed on the inter-layer insulation film 406 and contact a portion of the upper surface of the second auxiliary electrode 403c through a contact hole.

As described above, the first auxiliary electrode 403b may be an auxiliary electrode mediating the electrical connection between the first active layer 403a and the drain electrode 408, and the second auxiliary electrode 403c may be an auxiliary electrode mediating the electrical connection between the first active layer 403a and the source electrode 407.

Further, referring to FIG. 4, the inter-layer insulation film 406 may be disposed to surround upper and side surfaces of the second active pattern 322.

A first color filter RCF may be disposed on the inter-layer insulation film 406. As illustrated in FIG. 4, the first color filter RCF may be disposed to overlap at least a portion of the second active pattern 322.

At least a portion of the second active pattern 322 and at least a portion of the first color filter RCF may overlap the first emission area EA1.

An overcoat layer 409 may be disposed on the substrate 401 on which the first color filter RCF is disposed.

The first anode electrode AE1 of the first light emitting element ED1 may be disposed on the overcoat layer 409.

The first anode electrode AE1 may be electrically connected to the source electrode 407 of the thin film transistor through the contact hole provided in the overcoat layer 409. Although FIG. 4 illustrates a structure in which the first anode electrode AE1 is connected to the source electrode 407 of the thin film transistor, the structure of the display panel 110 according to the present embodiments is not limited thereto, and the first anode electrode AE1 may be connected to the drain electrode 408 of the thin film transistor.

Further, referring to FIG. 4, a bank BK may be disposed on a portion of the upper surface of the overcoat layer 409 and the first anode electrode AE1.

The bank BK may be disposed to overlap a portion of the upper surface of the first anode electrode AE1. The bank BK may be disposed to expose a portion of the upper surface of the first anode electrode AE′.

The bank BK may define an emission area EA and a non-emission area NEA within the display area DA of the display panel 110. For example, the area in which the bank BK is disposed in the display area DA may be a non-emission area NEA, and the area in which the bank BK is not disposed in the display area DA may be an emission area EA.

The light emitting layer EL of the first light emitting element ED1 may be disposed on the first anode electrode AE1.

Although FIG. 4 illustrates a structure in which the light emitting layer EL is a single layer, embodiments of the disclosure are not limited thereto. The light emitting layer EL may be formed of a multi-layered organic layer.

A cathode electrode CE of a first light emitting element ED1 may be disposed on the substrate 401 on which the light emitting layer EL is disposed.

The first anode electrode AE1 may include a transparent conductive material, and the cathode electrode CE may include a reflective conductive material, but embodiments of the disclosure are not limited thereto.

Further, FIG. 4 illustrates a structure in which the first anode electrode AE1 and the cathode electrode CE are a single layer, but embodiments of the disclosure are not limited thereto, and the first anode electrode AE1 and the cathode electrode CE may be formed in a multilayer structure of two or more layers.

An encapsulation layer 430 may be disposed on the cathode electrode CE.

The encapsulation layer 430 may include a first encapsulation layer 431 disposed on the cathode electrode CE, a second encapsulation layer 432 disposed on the first encapsulation layer 431, and a third encapsulation layer 433 disposed on the second encapsulation layer 432. The first and third encapsulation layers 431 and 433 may include an inorganic insulating material, and the second encapsulation layer 432 may include an organic insulating material.

Referring to FIG. 4, the second active pattern 322 may include at least one first cutting area CL1 in an area overlapping the first emission area EA1.

In other words, in the process of repairing the first subpixel SP1, a laser beam may be radiated to the first cutting line CL1 of the second active pattern 322 present in the first emission area EA1.

According to embodiments of the disclosure, there may be provided a display panel and a display device, capable of preventing or at least reducing a reduction in opening area due to the repair pattern by forming the first and second patterns 322a and 322b of the second active pattern 322 of an oxide semiconductor material and transparent conductive material, respectively, and using the second active pattern 322 as a repair pattern.

When the repair process is performed through the metal layer (e.g., gate metal), a laser beam with a longer wavelength than that used in the repair process using the second active pattern 322 disposed on the display panel 110 according to various embodiments of the disclosure may be used.

When the repair process is performed using a laser beam having a long wavelength, not only the repair pattern, which is irradiated with a laser beam, but also other lines or electrodes including metal may fail to operate normally due to the influence of the laser beam, causing a bright or dark spot or line.

Further, when the metal layer is used as the repair pattern, the emission area EA may be decreased in size due to the area occupied by the repair pattern that should be disposed in the non-emission area due to its opaqueness, deteriorating ghosting prevention performance.

As illustrated in FIG. 4, the display panel 110 according to embodiments of the disclosure uses the second active pattern 322 including the first pattern 322a formed of an oxide semiconductor material and the second pattern 322b formed of a transparent conductive material, as the repair pattern to allow the repair process to be performed with a short-wavelength laser beam as compared with when the metal layer is used as the repair pattern, thus preventing damage to other lines during the repair pattern.

In particular, since the cathode electrode CE is not damaged by the laser beam, it is also possible to prevent secondary defects that may be caused by external elements that may penetrate from the encapsulation layer 430 disposed on the cathode electrode CE.

Referring to FIG. 5, a laser beam may be radiated to the second active pattern 322 during the repair process of the first subpixel SP1 so that the second active pattern 322 may be cut.

In the repair process, the area in which the laser beam is radiated to the second active pattern 322 may have a structure in which the first color filter RCF is disposed on the second active pattern 322, the overcoat layer 409 is disposed on the first color filter RCF, the first anode electrode AE1 is disposed on the overcoat layer 409, and the light emitting layer EL and the cathode electrode CE are disposed on the anode electrode AE1.

As described above, since the first pattern 322a is formed of an oxide semiconductor material and the second pattern 322b is formed of a transparent conductive oxide, laser power may be reduced during a repair process compared to if metal was used as the repair pattern. In other words, the repair process may be performed using a low-wavelength laser beam. For example, the wavelength of the laser radiated in the repair process may be 250 nm to 350 nm, and a laser beam having a wavelength of 260 nm to 270 nm may be used.

Here, the first pattern 322a may have a thickness in a range of 200 Å to 500 Å. When the thickness of the first pattern 322a is less than 200 Å, uniformity of the first pattern 322a may be deteriorated. Further, when the thickness of the first pattern 322a exceeds 500 Å, electrical characteristics of the first active pattern 321 serving as a line may deteriorate due to reduced mobility.

The second pattern 322b may have a thickness in a range of 70 Å to 100 Å. When the thickness of the second pattern 322b is less than 70 Å, electrical conductivity of the first active pattern 321 including the second pattern 322b may decrease. Further, when the thickness of the second pattern 322b exceeds 100 Å, the etching rate of the second pattern 322b including the transparent conductive oxide increases, and thus the processing time may increase.

A plurality of other active patterns and active layers of thin film transistors may be formed in the same process as the process of forming the second active pattern 322 including the first pattern 322a and the second pattern 322b.

Even when a low-power laser beam is radiated to the second active pattern 322 including the first pattern 322a and the second pattern 322b, a portion of the laser beam passes through the second active pattern 322 and may also affect other components disposed on the second active pattern 322.

As illustrated in FIG. 5, the laser beam radiated to the second active pattern 322 may cut the second active pattern 322 and may even reach the first color filter RCF.

However, since the wavelength of the laser beam radiated in the process of repairing the subpixel SP of the display panel 110 according to embodiments of the disclosure is 250 nm to 350 nm, it is not transmitted through the first color filter RCF.

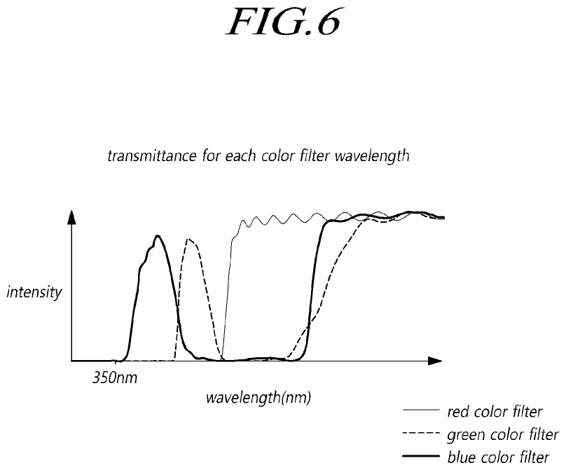

This is described below in detail with reference to FIG. 6.

FIG. 6 is a graph illustrating transmittance for each wavelength of a red color filter, a green color filter, and a blue color filter according to one embodiment.

Referring to FIG. 6, it may be identified that each of the red color filter, the green color filter, and the blue color filter does not transmit a wavelength of 350 nm or less at all.

Therefore, since the laser beam radiated to the second active pattern 322 may not pass through the first color filter RCF, it may not reach the first anode electrode AE1 and the cathode electrode CE disposed on the first color filter RCF. In other words, in the repair process of the second active pattern 322, the first anode electrode AE1 and the cathode electrode CE may not be damaged by the laser.

Although FIGS. 4 and 5 illustrate an example in which a laser beam is radiated to the first cutting area CL1 of the second active pattern 322 in the process of repairing the first subpixel SP1, the structure and effects may be applied to the first and second cutting areas CL1 and CL2 of the first subpixel SP1 and the second subpixel SP2 shown in FIG. 3.

Additionally, in FIG. 3, a fifth cutting area CL5 for repairing the first subpixel SP1 may be further included, and the fifth cutting area CL5 may be provided in the first active pattern 321,

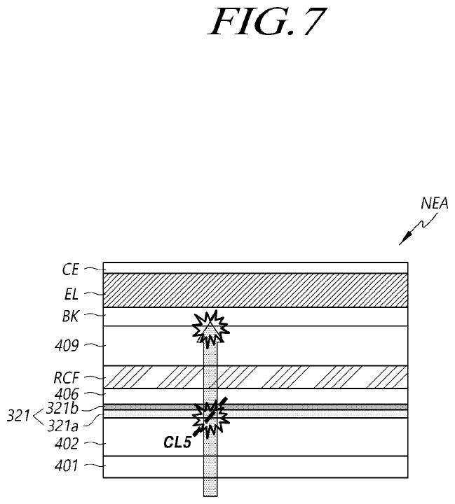

This is described below with reference to FIG. 7.

FIG. 7 is a view schematically illustrating a laser radiation to a fifth cutting area CL5 of a first active pattern in a process of repairing the first subpixel of FIG. 3.

Referring to FIGS. 3 and 7, the fifth cutting area CL5 of the first active pattern 321 used to repair the first subpixel SP1 may be disposed in the non-emission area NEA.

The fifth cutting area CL5 of the first active pattern 321 may not overlap the first anode electrode AE1 but may overlap the bank BK.

Specifically, referring to FIG. 7, the first color filter RCF may be disposed on the first active pattern 321 including the fifth cutting area CL5, the overcoat layer 409 may be disposed on the first color filter RCF, the bank BK may be disposed on the overcoat layer 409, and the light emitting layer EL and the cathode electrode CE may be disposed on the bank BK.

The bank BK may be a black bank. In one embodiment, a black bank is a bank including black material such as black ink.

As the first pattern 321a (e.g., a first layer) of the first active pattern 321 is formed of an oxide semiconductor material and the second pattern 322b (e.g., a second layer) of the first active pattern 321 is formed of a transparent conductive oxide, laser power may be reduced during a repair process.

The wavelength of the laser radiated in the repair process may be in a range 250 nm to 350 nm, and a laser beam having a wavelength in a range of 260 nm to 270 nm may be used.

As illustrated in FIG. 7, the laser beam radiated to the second active pattern 322 may cut the second active pattern 322 thereby disconnecting the first subpixel SP1 from the second signal line SL2, and a portion thereof may even reach the first color filter RCF.

As described above, the first color filter RCF may absorb the laser beam without transmitting it.

However, in the display panel 110 according to embodiments of the disclosure, in addition to the first color filter RCF, the black bank BK may be disposed on the first active pattern 321 having the fifth cutting area CL5 irradiated with the laser beam to protect the cathode electrode CE disposed on the first active pattern 321, thus preventing the laser beam from reaching the cathode electrode CE.

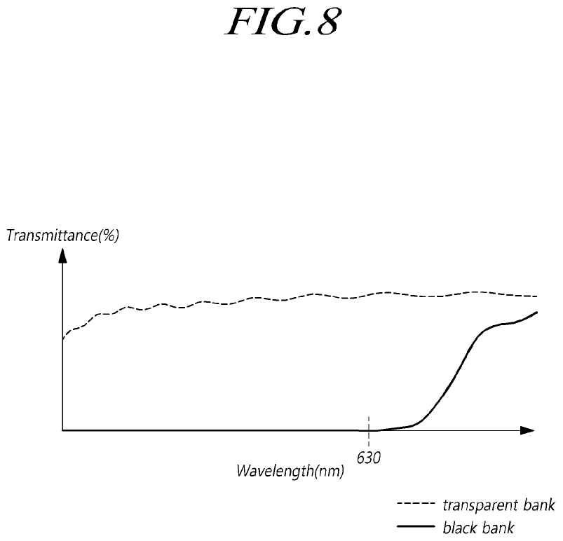

This is described below in detail with reference to FIG. 8.

FIG. 8 is a graph illustrating transmittance for each wavelength of each of a transparent bank and a black bank.

The graph of FIG. 8 illustrates the transmittance of light in the visible ray wavelength range at a thickness of 1.5 μm for each of the transparent bank and the black bank.

Referring to FIG. 8, it may be identified that the transparent bank transmits more than 70% of the visible light wavelength range.

On the other hand, since the black bank does not transmit light of 630 nm or less, it may be identified that it may not transmit a laser beam having a wavelength of 250 nm to 350 nm.

As such, when a laser beam is radiated to the fifth cutting area CL5 of the second active pattern 322 in the process of repairing the first subpixel SP1, the laser beam may be prevented from reaching the cathode electrode CE by the first color filter RCF and the bank BK disposed on the second active pattern 322, preventing damage to the cathode electrode CE due to the laser beam.

In summary, in the process of repairing the first and second subpixels SP1 and SP2, the active patterns 321, 322, 331, and 332 may be irradiated with a laser beam to disconnect the first and second subpixels SP1 and SP2 from the signal lines connected to the active patterns 321, 322, 331, and 332, and the cutting area irradiated with the laser beam may be present in the emission area EA or non-emission area NEA.

Specifically, when the cutting area for repairing the first and second subpixels SP1 and SP2 is present in the emission area (first emission area EA1 or second emission area EA2), the active pattern having the cutting area may overlap the color filter (first color filter RCF or second color filter BCF), preventing the laser beam from reaching the anode electrode AE and the cathode electrode CE.

Further, when the cutting area for repairing the first and second subpixels SP1 and SP2 is present in the non-emission area NEA, the active pattern having the cutting area may overlap the color filter (first color filter RCF or second color filter BCF) and bank BK, preventing the laser beam from reaching the cathode electrode CE disposed on the bank BK.

Meanwhile, cutting areas for repairing the third subpixel SP3 and the fourth subpixel SP4 may not overlap the emission area EA (see FIG. 3).

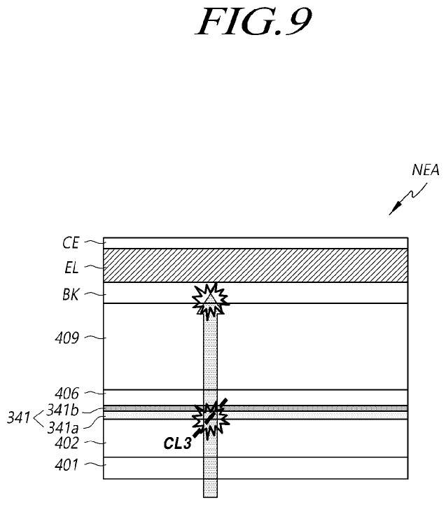

In other words, the cutting areas for repairing the third subpixel SP3 and the fourth subpixel SP4 may be disposed only in the non-emission area NEA, which is described below with reference to FIG. 9.

FIG. 9 is a view schematically illustrating a laser radiation to a third cutting area CL3 of a seventh active pattern 341 in a process of repairing the third subpixel of FIG. 3. FIG. 9 illustrates an example configuration in which the seventh active pattern 341 is

cut as a laser beam is radiated to the third cutting area CL3 of the seventh active pattern 341, but the eighth active pattern 342 disposed in the third subpixel SP3 may have the same stack structure in the area where the third cutting area CL3 is provided. Further, the tenth active pattern 351 and the eleventh active pattern 352 of the fourth subpixel SP4 may also have the same stack structure as that of FIG. 9 in the area where the fourth cutting area CL4 is present.

Referring to FIG. 9, the third cutting area CL3 of the seventh active pattern 341 used to repair the third subpixel SP3 may be disposed in the non-emission area NEA.

The third cutting area CL3 of the seventh active pattern 341 may not overlap the third anode electrode AE3 but may overlap the bank BK.

Specifically, referring to FIG. 9, the overcoat layer 409 may be disposed on the seventh active pattern 341 including the third cutting area CL3, the bank BK may be disposed on the overcoat layer 409, and the light emitting layer EL and the cathode electrode CE may be disposed on the bank BK.

The bank BK may be a black bank.

As the first pattern 341a of the seventh active pattern 341 is formed of an oxide semiconductor material and the second pattern 341b of the seventh active pattern 341 is formed of a transparent conductive oxide, a low-wavelength laser beam may be used during a repair process. For example, the wavelength of the laser radiated in the repair process may be in a range of 250 nm to 350 nm, and a laser beam having a wavelength in a range of 260 nm to 270 nm may be used.

As illustrated in FIG. 9, the laser beam radiated to the seventh active pattern 341 may cut the seventh active pattern 341 thereby disconnecting the third subpixel SP3 from the fourth signal line SL4, and a portion thereof may even reach the bank BK.

As described above, the bank BK according to embodiments of the disclosure does not transmit light of 630 nm or less, and thus may not transmit laser beams having a wavelength of 250 nm to 350 nm.

Accordingly, when a laser beam is radiated to the third cutting area CL3 of the seventh active pattern 341 in the process of repairing the third subpixel SP3, the laser beam may be prevented from reaching the cathode electrode CE by the bank BK disposed on the first active pattern 341, preventing damage to the cathode electrode CE.

Although FIGS. 3 to 9 illustrate a configuration of radiating a laser beam to active patterns electrically connected with the second signal line SL2 or third signal line SL3 which are data lines for repairing the first to fourth subpixels SP1, SP2, SP3, and SP4 or active patterns electrically connected with the fourth signal line SL4 which is the reference voltage line, embodiments of the disclosure are not limited thereto.

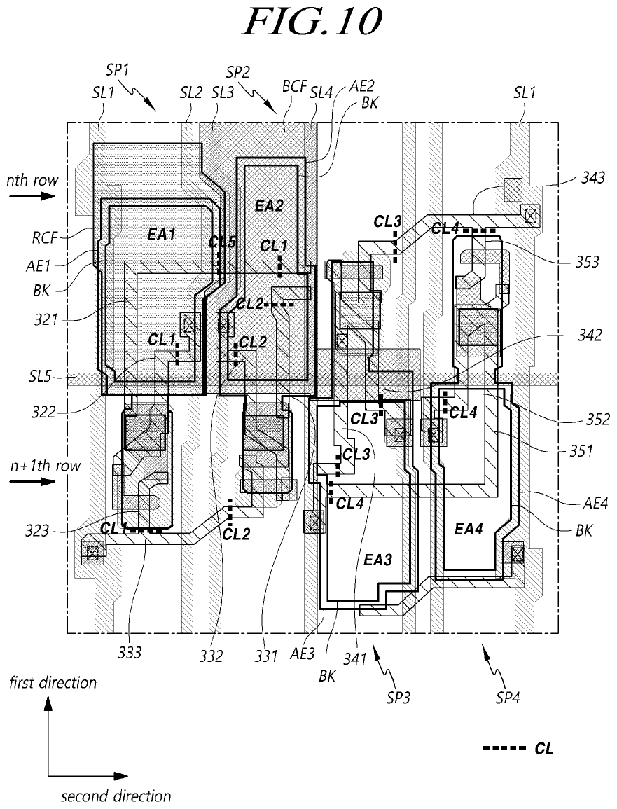

Referring to FIGS. 10 to 12, a structure of a display panel according to embodiments of the disclosure is described below.

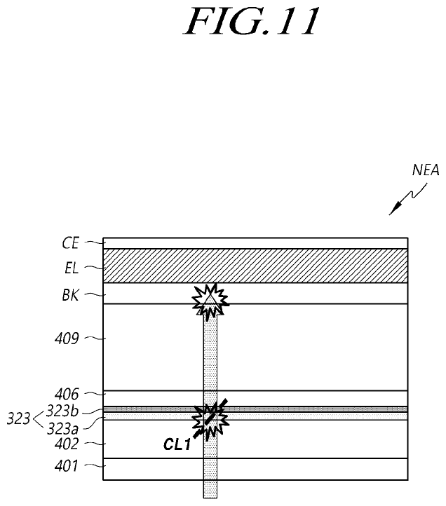

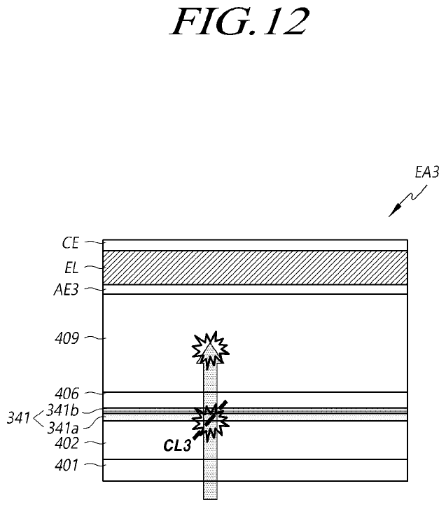

FIG. 10 is a view illustrating a structure of first to fourth subpixels included in a display panel according to embodiments of the disclosure. FIG. 11 is a view schematically illustrating a laser radiation to a first cutting area of a third active pattern in a process of repairing a first subpixel according to embodiments of the disclosure. FIG. 12 is a view schematically illustrating a laser radiation to a third cutting area of a seventh active pattern in a process of repairing the third subpixel of FIG. 10 according to embodiments of the disclosure.

The structures of the first to fourth subpixels SP1, SP2, SP3, and SP4 shown in FIG. 10 may be substantially the same as those of the first to fourth subpixels SP1, SP2, SP3, and SP4 shown in FIG. 3.

As compared with FIG. 3, FIG. 10 differs in the configuration in which at least one cutting area is provided in each of the third active pattern 323 disposed in the first subpixel SP1, the sixth active pattern 333 disposed in the second subpixel SP2, the ninth active pattern 343 disposed in the third subpixel SP3, and the twelfth active pattern 353 disposed in the fourth subpixel SP4.

Specifically, referring to FIG. 10, each of the third active pattern 323, sixth active pattern 333, ninth active pattern 343, and twelfth active pattern 353 may be connected to the first signal line SL1 and serve as a line.

The third active pattern 323 may include a first cutting area CL1 to which a laser beam may be radiated in the repair process of the first subpixel SP1.

The sixth active pattern 333 may include a second cutting area CL2 to which a laser beam may be radiated in the repair process of the second subpixel SP2.

The ninth active pattern 343 may include a third cutting area CL3 to which a laser beam may be radiated in the repair process of the third subpixel SP3.

The twelfth active pattern 353 may include a fourth cutting area CL4 to which a laser beam may be radiated in the repair process of the fourth subpixel SP4.

Referring to FIG. 10, each of the first cutting area CL1 provided in the third active pattern 323, the second cutting area CL2 provided in the sixth active pattern 333, the third cutting area CL3 provided in the ninth active pattern 343, and the fourth cutting area CL4 provided in the twelfth active pattern 353 may be disposed in the non-emission area NEA, and may not overlap the anode electrodes AE1, AE2, AE3, and AE4.

Referring to FIG. 11, the first cutting area CL1 of the third active pattern 323 used to repair the first subpixel SP1 may be disposed in the non-emission area NEA.

The first cutting area CL1 of the third active pattern 323 may not overlap the first anode electrode AE1 and may overlap the bank BK.

Specifically, referring to FIG. 11, the overcoat layer 409 may be disposed on the third active pattern 323 including the first cutting area CL1, the bank BK may be disposed on the overcoat layer 409, and the light emitting layer EL and the cathode electrode CE may be disposed on the bank BK.

The first pattern 323a of the third active pattern 323 may be formed of an oxide semiconductor material, and the second pattern 323b of the third active pattern 323 may be formed of a transparent conductive oxide. Further, in the repair process, the wavelength of the laser beam radiated to the first cutting area CL1 of the third active pattern 323 may be in a range of 250 nm to 350 nm, and a laser beam having a wavelength in a range of 260 nm to 270 nm may be used.

As illustrated in FIG. 11, the laser beam radiated to the third active pattern 323 may cut the third active pattern 323 thereby disconnecting the first subpixel SP1 from the first signal line SL1, and a portion thereof may reach the bank BK disposed on the third active pattern 323.

The bank BK according to embodiments of the disclosure may not transmit light of 630 nm or less, and thus may not transmit a laser beam having a wavelength of 250 nm to 350 nm.

Accordingly, when the laser beam is radiated to the first cutting area CL1 of the third active pattern 323 in the process of repairing the first subpixel SP1, the laser beam may not reach the cathode electrode CE due to the bank BK disposed on the third active pattern 323, thereby preventing the cathode electrode CE from being damaged.

Although FIG. 11 exemplarily illustrates a stack structure for an area in which the first cutting area CL1 of the third active pattern 323 disposed in the first subpixel SP1 may be provided, the stack structure of the area in which the respective cutting areas of the sixth active pattern 333 disposed in the second subpixel SP2, the ninth active pattern 343 disposed in the third subpixel SP3, and the twelfth active pattern 353 disposed in the fourth subpixel SP4 may be the same as the structure of FIG. 11.

Additionally, as the structure of FIG. 10 is compared with FIG. 3, the positions of the third cutting area CL3 provided in each of the seventh and eighth active patterns 341 and 342 disposed in the third subpixel SP3 and the fourth cutting area CL4 provided in each of the tenth and eleventh active patterns 351 and 352 disposed in the fourth subpixel SP4 may be different.

Specifically, referring to FIG. 10, in an area in which the third cutting area CL3 is provided, each of the seventh and eighth active patterns 341 and 342 may not overlap the bank BK and may overlap the third anode electrode AE3.

Further, referring to FIG. 10, in an area in which the fourth cutting area CL4 is provided, the tenth active pattern 351 may not overlap the bank BK and may overlap the third anode electrode AE3. Further, in an area in which the fourth cutting area CL4 is provided, the eleventh active pattern 352 may not overlap the bank BK and may overlap the fourth anode electrode AE4.

In other words, the active patterns 341, 342, 351, and 352 connected to the data line or the reference voltage line in the third and fourth subpixels SP4 may overlap one anode electrode AE in a portion where the cutting area CL is positioned and may not overlap the bank BK, and thus may have a structure overlapping one emission area EA.

Referring to FIG. 10, in an area in which the third cutting area CL3 is provided, each of the seventh and eighth active patterns 341 and 342 may overlap at least a portion of the third emission area EA3. Further, in an area in which the fourth cutting area CL4 is provided, the tenth active pattern 351 may overlap the third emission area EA3, and in an area in which the fourth cutting area CL4 is provided, the eleventh active pattern 352 may overlap the fourth emission area EA4.

As described above, the cutting areas CL of the active patterns 341, 342, 351, and 352 connected to the data line or the reference voltage line in the third and fourth subpixels SP4 may be disposed to overlap one emission area EA3 and EA4, thereby providing a repair area without decreasing the aperture ratio of the display panel 110.

For example, referring to FIG. 12, the third cutting area CL3 of the seventh active pattern 341 used to repair the third subpixel SP3 may be disposed in the third emission area EA3.

The third cutting area CL3 of the seventh active pattern 341 may overlap the third anode electrode AE3, the light emitting layer EL, and the cathode electrode CE, and may not overlap the bank BK.

Specifically, referring to FIG. 12, the inter-layer insulation layer 406 and the overcoat layer 409 may be disposed on the seventh active pattern 341 including the third cutting area CL3, the third anode electrode AE3 may be disposed on the overcoat layer 409, and the light emitting layer EL and the cathode electrode CE may be disposed on the third anode electrode AE3.

The first pattern 341a of the seventh active pattern 341 may be formed of an oxide semiconductor material, and the second pattern 341b of the seventh active pattern 341 may be formed of a transparent conductive oxide. Further, the wavelength of the laser beam radiated to the third cutting area CL3 of the seventh active pattern 341 in the repair process may be 250 nm to 350 nm, and a laser beam having a wavelength of 260 nm to 270 nm may be used.

As illustrated in FIG. 12, the laser beam radiated to the seventh active pattern 341 may cut the seventh active pattern 341 thereby disconnecting the third subpixel SP4 from the fourth signal line SL4, and a portion thereof may reach the overcoat layer 409 disposed on the seventh active pattern 341.

As illustrated in FIG. 12, the laser beam reaching the overcoat layer 409 may be absorbed by the overcoat layer 409, and thus the laser beam may not reach the third anode electrode AE3 and the cathode electrode CE.

In this case, the thickness of the overcoat layer 409 may be 10 times or more than the thickness of the light emitting layer EL including a plurality of organic layers.

Although FIG. 12 exemplarily illustrates a stack structure for an area in which the third cutting area CL3 of the seventh active pattern 341 disposed in the third subpixel SP3 may be provided, the stack structure of the area in which the cutting areas of each of the eighth active pattern 342 disposed in the third subpixel SP3, the tenth active pattern 351 disposed in the fourth subpixel SP4, and the eleventh active pattern 352 disposed in the fourth subpixel SP4 may be the same as the structure of FIG. 12.

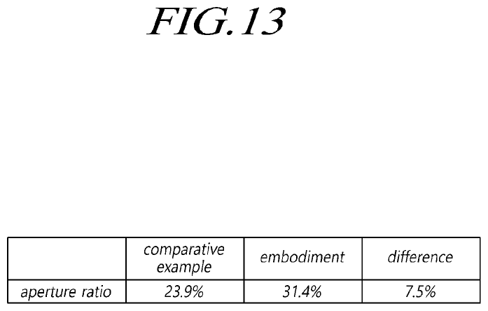

FIG. 13 is a table comparing an aperture ratio of a display panel according to a comparative example and an aperture ratio of a display panel according to an embodiment.

In FIG. 13, the display panel according to the comparative example is a display panel having a repair pattern formed of a metal layer and disposed in a non-emission area, and the display panel according to the embodiment is a display panel having the structure of FIG. 3.

Referring to FIG. 13, it may be identified that the aperture ratio of the display panel according to the embodiment is 7.5% larger than the aperture ratio of the display panel according to the comparative example.

In other words, as the aperture ratio of the display panel according to the embodiment is enhanced, the luminous efficiency is enhanced, and thus it is possible to drive the display panel with low power.

According to embodiments of the disclosure, there may be provided a display panel and a display device capable of preventing or at least reducing a reduction in opening area due to a repair pattern by using a transparent active pattern, which serves as a line, as the repair pattern.

According to embodiments of the disclosure, there may be provided a display panel and a display device capable of preventing or at least reducing damage to the cathode electrode and the anode electrode due to a laser radiation during a repair process by disposing at least one of a color filter, a black bank, and an overcoat layer on the active pattern.

According to embodiments of the disclosure, there may be provided a display panel and a display device capable of preventing or at least reducing defects due to an external element penetrated from the encapsulation layer disposed on the cathode electrode by preventing damage to the cathode electrode due to failure of a laser beam to reach the cathode electrode by performing a repair process using a transparent active pattern as a repair pattern.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display panel, comprising:
a substrate comprising plurality of subpixels, the plurality of subpixels including a first subpixel, a second subpixel, a third subpixel, and a fourth subpixel each including an emission area and a non-emission area surrounding the emission area; and
a plurality of signal lines on the substrate, the plurality of signals lines including a first signal line, a second signal line, a third signal line, and a fourth signal line that are spaced apart from each other,
wherein each of the first subpixel to the fourth subpixel includes a plurality of active patterns on the substrate, the plurality of active patterns including a first active pattern, a second active pattern, and a third active pattern,
wherein the first active pattern of at least one of the first subpixel to the fourth subpixel is electrically connected to the fourth signal line, the second active pattern of at least one of the first subpixel to the fourth subpixel is electrically connected to one of the second signal line or the third signal line, and the third active pattern of at least one of the first subpixel to the fourth subpixel is electrically connected to the first signal line,
wherein at least one of the first active pattern to the third active pattern of at least one of the first subpixel to the fourth subpixel includes a cutting area configured to disconnect the at least one of the first
subpixel to the fourth subpixel from at least one of the plurality of signal lines,
wherein cutting areas of the first active pattern and the second active pattern in the first subpixel and the second subpixel overlap the emission area, and
wherein at least one cutting area of the first active pattern to the third active pattern in the third subpixel and the fourth subpixel is in the non-emission area.

2. The display panel of claim 1, wherein the emission area included in the first subpixel overlaps a first color filter of the first subpixel, the emission area included in the second subpixel overlaps a second color filter of the second subpixel, and the emission area included in the third subpixel is non-overlapping with any color filter.

3. The display panel of claim 1, wherein the first subpixel includes a first emission area, the second subpixel includes a second emission area, the third subpixel includes a third emission area, and the fourth subpixel includes a fourth emission area,
wherein the first emission area and the second emission area are in a first row of subpixels, and the third emission area and the fourth emission area are in a second row of subpixels that is different from the first row.

4. The display panel of claim 1, further comprising:
a first color filter on the second active pattern of the first subpixel, the first color filter overlapping the cutting area of the second active pattern of the first subpixel;
an overcoat layer on the first color filter,
a first anode electrode on the overcoat layer;
a first light emitting layer on the first anode electrode; and
a first cathode electrode on the light emitting layer.

5. The display panel of claim 4, wherein the cutting area of the second active pattern of the first subpixel overlaps a first emission area included in the first subpixel, the first emission area comprising overlapping portions of the first anode electrode, the first light emitting layer, and the first cathode electrode.

6. The display panel of claim 4, further comprising:
a second color filter on the first active pattern of the first subpixel, the second color filter overlapping the cutting area of the first active pattern included in the first subpixel;
a second anode electrode on the overcoat layer;
a second light emitting layer on the second anode electrode; and
a second cathode electrode on the second light emitting layer,
wherein the overcoat layer is on the second color filter.

7. The display panel of claim 6, wherein the cutting area of the first active pattern included in the first subpixel overlaps a second emission area included in the second subpixel, the second emission area comprising overlapping portions of the second anode electrode, the second light emitting layer, and the second cathode electrode.

8. The display panel of claim 4, further comprising:
a second color filter on the first active pattern and the second active pattern of the second subpixel, the second color filter overlapping the cutting area of the first active pattern and the cutting area of the second active pattern of the second subpixel;
a second anode electrode on the overcoat layer;
a second light emitting layer on the second anode electrode;
a second cathode electrode on the second light emitting layer,
wherein the overcoat layer is on the second color filter.

9. The display panel of claim 8, wherein the cutting area of the first active pattern and the cutting area of the second active pattern in the second subpixel overlaps a second emission area included in the second subpixel, the second emission area comprising overlapping portions of the second anode electrode, the second light emitting layer, and the second cathode electrode.

10. The display panel of claim 1, further comprising:
a first color filter on the first active pattern of the first subpixel, the first color filter non-overlapping with the cutting area of the first active pattern of the first subpixel;
an overcoat layer on the first color filter;
a black bank on the overcoat layer;
a light emitting layer on the black bank; and
a cathode electrode on the first light emitting layer.

11. The display panel of claim 10, wherein the cutting area of the first active pattern of the first subpixel overlaps the non-emission area of the first subpixel, the non-emission area of the first subpixel comprising overlapping portions of the black bank, the light emitting layer, and the cathode electrode.

12. The display panel of claim 1, further comprising:
an overcoat layer on the first active pattern and the second active pattern of the third subpixel, the overcoat layer overlapping the cutting area of the first active pattern of the third subpixel and the cutting area of the second active pattern of the third subpixel;
a black bank on the overcoat layer,
a light emitting layer on the black bank; and
a cathode electrode on the light emitting layer.

13. The display panel of claim 12, wherein the cutting area of the first active pattern and the cutting area of the second active pattern of the third subpixel overlaps the non-emission area of the third subpixel, the non-emission area of the third subpixel comprising overlapping portions of the black bank, the light emitting layer, and the cathode electrode.

14. The display panel of claim 1, further comprising:
an overcoat layer on the first active pattern and the second active pattern in the fourth subpixel, the overcoat layer overlapping the cutting area of the first active pattern and the cutting area of the second active pattern of the fourth subpixel;
a black bank on the overcoat layer,
a light emitting layer on the black bank; and
a cathode electrode on the light emitting layer.

15. The display panel of claim 14, wherein the cutting area of the first active pattern of the fourth subpixel overlaps the non-emission area included in the third subpixel, and the cutting area of the second active pattern in the fourth subpixel overlaps the non-emission area included in the fourth subpixel, the non-emission area of the fourth subpixel comprising overlapping portions of the black bank, the light emitting layer, and the cathode electrode.

16. The display panel of claim 1, further comprising:
an overcoat layer on the first active pattern and the second active pattern of the third subpixel, the overcoat layer overlapping the cutting area of the first active pattern and the cutting area of the second active patterns of the third subpixel;
a third anode electrode on the overcoat layer;
a light emitting layer on the third anode electrode, and
a cathode electrode on the light emitting layer.

17. The display panel of claim 16, wherein the cutting area of the first active pattern and the cutting area of the second active pattern of the third subpixel overlaps a third emission area of the third subpixel, the third emission area comprising overlapping portions of the third anode electrode, the light emitting layer, and the cathode electrode.

18. The display panel of claim 1, further comprising:
an overcoat layer on the first active pattern of the fourth subpixel, the overcoat layer overlapping the cutting area of the first active pattern of the fourth subpixel;
a third anode electrode on the overcoat layer;
a light emitting layer on the third anode electrode, and
a cathode electrode on the light emitting layer.

19. The display panel of claim 18, wherein the cutting area of the first active pattern included in the fourth subpixel overlaps a third emission area included in the third subpixel, the third emission area comprising overlapping portions of the third anode electrode, the light emitting layer, and the cathode electrode.

20. The display panel of claim 1, further comprising:
an overcoat layer on the second active pattern of the fourth subpixel, the overcoat layer overlapping the cutting area of the second active pattern of the fourth subpixel;
a fourth anode electrode on the overcoat layer;
a light emitting layer on the fourth anode electrode; and
a cathode electrode on the light emitting layer.

21. The display panel of claim 20, wherein the cutting area of the second active pattern included in the fourth subpixel overlaps a fourth emission area included in the fourth subpixel, the fourth emission area comprising overlapping portions of the fourth anode electrode, the light emitting layer, and the cathode electrode.

22. The display panel of claim 1, wherein the cutting area of the third active pattern in each of the first subpixel to the fourth subpixel is in the respective non-emission area of the first subpixel to the fourth subpixel.

23. The display panel of claim 1, wherein each of the first active pattern to the third active pattern includes a first pattern and a second pattern on the first pattern, wherein the first pattern includes an oxide semiconductor material, and the second pattern includes a transparent conductive oxide.

24. The display panel of claim 1, wherein the first signal line is a driving voltage line, the second signal line and the third signal lines are data lines, and the fourth signal line is a reference voltage line.

25. The display panel of claim 1, wherein the cutting area of each of the first active pattern to the third active pattern is configured to be supplied a laser beam.

26. A display panel comprising:
a substrate;
a bank on the substrate, the bank including an opening;
a subpixel on the substrate, the subpixel including a thin film transistor and a light emitting element connected to the thin film transistor, the light emitting element in the opening of the bank and including an anode electrode, a light emitting layer on the anode electrode, and a cathode electrode on the light emitting layer;
a first signal line configured to supply a first signal to the subpixel; and
a first active pattern comprising a first cutting area that disconnects the first signal line and the subpixel, the first cutting area overlapping the light emitting element,
wherein the first active pattern comprises a material having oxide.

27. The display panel of claim 26, further comprising:
a second signal line configured to supply a second signal to the subpixel; and
a second active pattern overlapping the light emitting element and comprising a second cutting area that disconnects the second signal line and the subpixel, the second cutting area overlapping the bank,
wherein the second active pattern comprises the material having oxide.

28. The display panel of claim 27, wherein the second active pattern overlaps a light emitting element of another subpixel.

29. The display panel of claim 26, further comprising:
a color filter between the first active pattern and the light emitting element, and the color filter overlapping the first active pattern and the light emitting element.

30. The display panel of claim 26, wherein the first active pattern comprises a first layer and a second layer on the first layer, the first layer including oxide semiconductor, and the second layer including transparent conductive oxide.

31. A display panel comprising:
a substrate;
a bank on the substrate, the bank including an opening;
a subpixel on the substrate, the subpixel including a thin film transistor and a light emitting element connected to the thin film transistor, the light emitting element in the opening of the bank and including an anode electrode, a light emitting layer on the anode electrode, and a cathode electrode on the light emitting layer;
a signal line configured to supply a signal to the subpixel; and
an active pattern comprising a cutting area that disconnects the signal line and the subpixel, the cutting area overlapping the bank and non-overlapping the light emitting element,
wherein the active pattern comprises a material having oxide.

32. The display panel of claim 31, wherein the first active pattern comprises a first layer and a second layer on the first layer, the first layer including oxide semiconductor, and the second including transparent conductive oxide.

33. The display panel of claim 31, wherein the bank comprises black material.
